(19) United States
(12) Patent Application Publication
(10) Pub. No.: US 2013/0221478 A1
(43) Pub. Date: Aug. 29, 2013

(54) METHODS OF FORMING ISOLATION STRUCTURES FOR SEMICONDUCTOR DEVICES BY EMPLOYING A SPIN-ON GLASS MATERIAL OR A FLOWABLE OXIDE MATERIAL

(71) Applicants: Stephan Kronholz, Dresden (DE); Jorg Radecker, Dresden (DE); Hans-Juergen Thees, Dresden (DE); Peter Javorka, Radeburg (DE)

(72) Inventors: Stephan Kronholz, Dresden (DE); Jorg Radecker, Dresden (DE); Hans-Juergen Thees, Dresden (DE); Peter Javorka, Radeburg (DE)

(73) Assignee: GLOBALFOUNDRIES INC., Grand Cayman (KY)

(21) Appl. No.: 13/405,713

(22) Filed: Feb. 27, 2012

(51) Int. Cl. H01L 29/06; H01L 21/762

(52) U.S. Cl. 257/506; 438/424; 257/E29.02; 257/E21.546

(57) ABSTRACT

Disclosed herein are various methods of forming isolation structures, such as trench isolation structures, for semiconductor devices using a spin-on glass material or a flowable oxide material. In one example, the method includes forming a trench in a semiconducting substrate, forming a lower isolation structure comprised of an insulating material in at least the trench, wherein the lower isolation structure has an upper surface that is below an upper surface of the substrate, and forming an upper isolation structure above the lower isolation structure, wherein a portion of the upper isolation structure is positioned within the trench.

### BACKGROUND OF THE INVENTION

1. Field of the Invention

Generally, the present disclosure relates to the manufacturing of sophisticated semiconductor devices, and, more specifically, to various methods of forming isolation structures, such as trench isolation structures, for semiconductor devices using a spin-on glass material or a flowable oxide material.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein field effect transistors (NMOS and PMOS transistors) represent one important type of circuit element used in manufacturing such integrated circuit devices. A field effect transistor, irrespective of whether an NMOS transistor or a PMOS transistor is considered, typically comprises doped source and drain regions that are formed in a semiconducting substrate that are separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

To make an integrated circuit on a semiconducting substrate, the various semiconductor devices, e.g., transistors, capacitors, etc., are electrically isolated from one another by so-called isolation structures. Currently, most sophisticated integrated circuit devices employ so-called shallow trench isolation (STI) structures. As the name implies, STI structures are made by forming a relatively shallow trench in the substrate and thereafter filling the trench with an insulating material, such as silicon dioxide. One technique used to form STI structures initially involves growing a pad oxide layer on the substrate and depositing a pad nitride layer on the pad oxide layer. Thereafter, using traditional photolithography and etching processes, the pad oxide layer and the pad nitride layer are patterned. Then, an etching process is performed to form trenches in the substrate for the STI structure using the patterned pad oxide layer and pad nitride layer as an etch mask. Thereafter, a deposition process is performed to overfill the trenches with an insulating material such as silicon dioxide. A chemical mechanical polishing (CMP) process is then performed using the pad nitride layer as a polish stop layer to remove the excess insulation material. Then, a subsequent deglazing (etching) process may be performed to insure that the insulating material is removed from the surface of the pad nitride layer. This deglaze process removes some of the STI structures.

Numerous processing operations are performed in a very detailed sequence, or process flow, to form such integrated circuit devices, e.g., deposition processes, etching processes, heating processes, masking operations, etc. One problem that arises with current processing techniques is that, after the STI regions are formed, at least portions of the STI regions are exposed to many subsequent etching or cleaning processes that tend to consume, at least to some degree, portions of the STI structures subjected to such etching processes. As a result, the STI structures may not perform their isolation function as intended, which may result in problems such as increased leakage currents, etc. Furthermore, since the erosion of the STI structures is not uniform across a die or a wafer, such structures may have differing heights, which can lead to problems in subsequent processing operations. For example, such height differences may lead to uneven surfaces on subsequently deposited layers of material, which may require additional polishing time in an attempt to planarize the surface of such layers. Such additional polishing may lead to the formation of additional particle defects, which may reduce device yields.

The present disclosure is directed to various methods of forming isolation structures that may eliminate or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming isolation structures, such as trench isolation structures, for semiconductor devices. In one example, the method includes forming a trench in a semiconducting substrate, forming a lower isolation structure comprised of an insulating material in at least the trench, wherein the lower isolation structure has an upper surface that is below an upper surface of the substrate, and forming an upper isolation structure above the lower isolation structure, wherein a portion of the upper isolation structure is positioned within the trench. In some embodiments, the insulating material may be a spin-on glass material or a flowable oxide material.

Another illustrative method disclosed herein includes the steps of forming a trench in a semiconducting substrate, performing a spin-coating process to position either a spin-on glass material or a flowable oxide material in the trench, after performing the spin-coating process, performing at least one heating process to at least partially cure the spin-on glass material or the flowable oxide material and thereby define a lower isolation structure in the trench, wherein the lower isolation structure has an upper surface that is below an upper surface of the substrate, and forming an upper isolation structure above the lower isolation structure, wherein a portion of the upper isolation structure is positioned within the trench.

An illustrative device disclosed herein includes a trench formed in a semiconducting substrate, a lower isolation structure comprised of a spin-on glass material or a flowable oxide material positioned in the trench, wherein the lower isolation structure has an upper surface that is below an upper surface of the substrate, and an upper isolation structure positioned above the lower isolation structure, wherein a portion of the upper isolation structure is positioned within the trench.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1H depict various novel methods disclosed herein for forming isolation structures for semiconductor devices; and

FIGS. 2A-2C depict other illustrative novel methods disclosed herein for forming isolation structures for semiconductor devices.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming isolation structures, such as trench isolation structures, for semiconductor devices using a spin-on glass and/or a flowable oxide material. As will be readily apparent to those skilled in the art upon a complete reading of the present application, the present method is applicable to a variety of devices, including, but not limited to, logic devices, memory devices, etc. With reference to the attached drawings, various illustrative embodiments of the methods and devices disclosed herein will now be described in more detail.

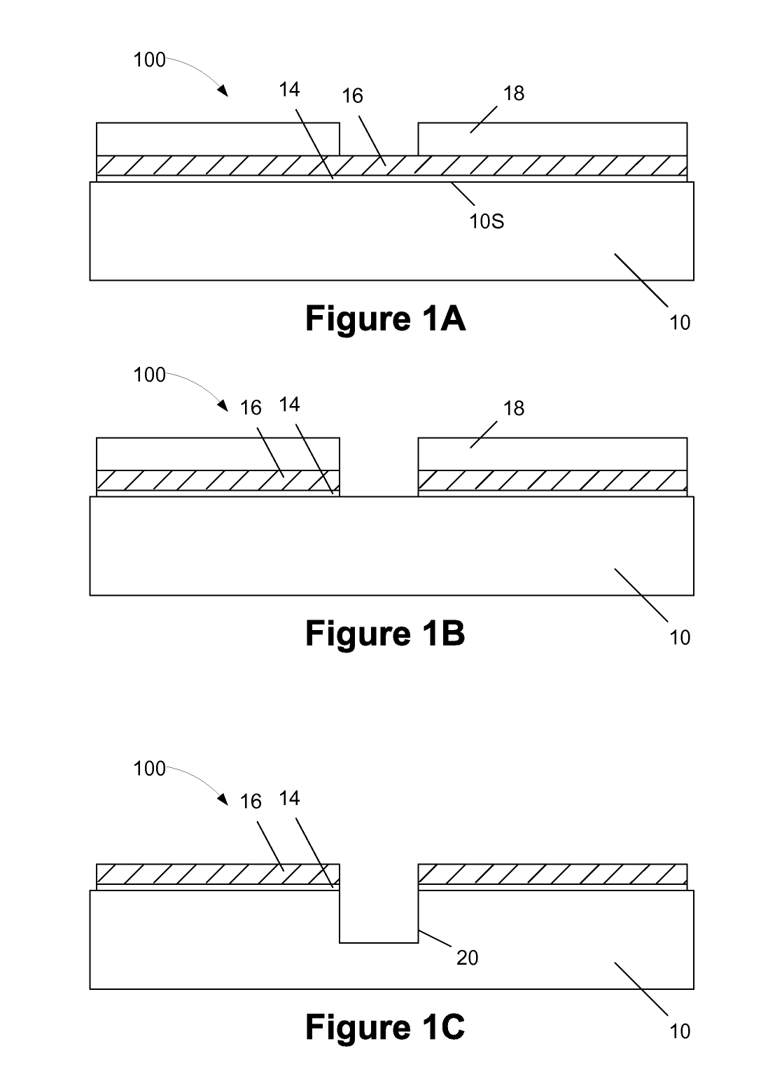

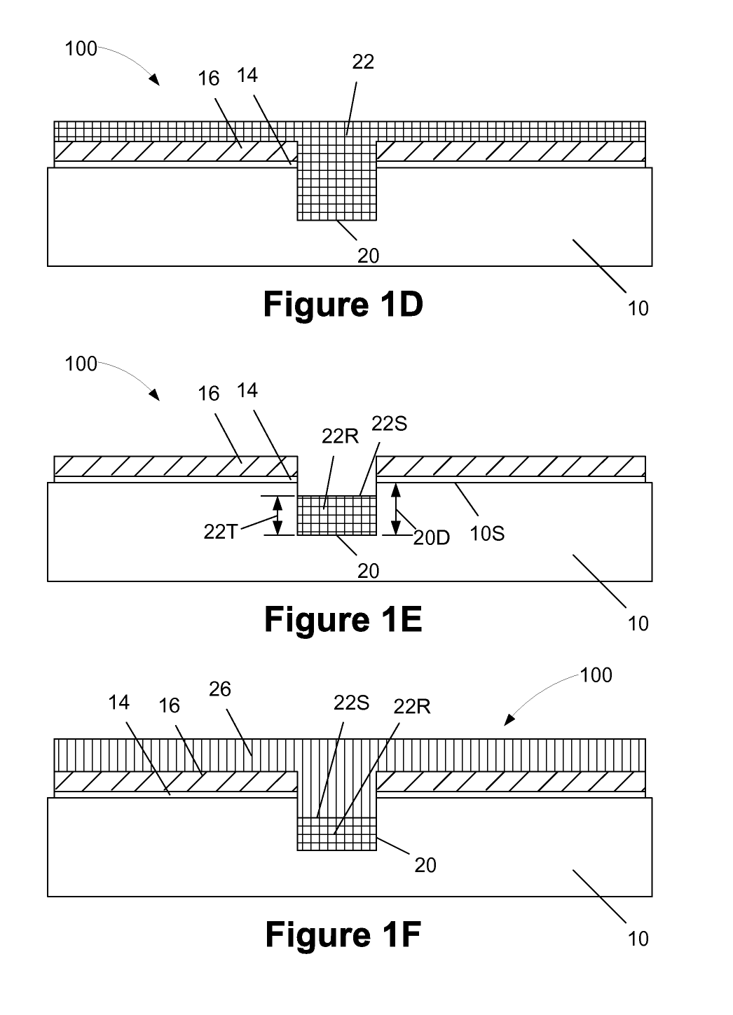

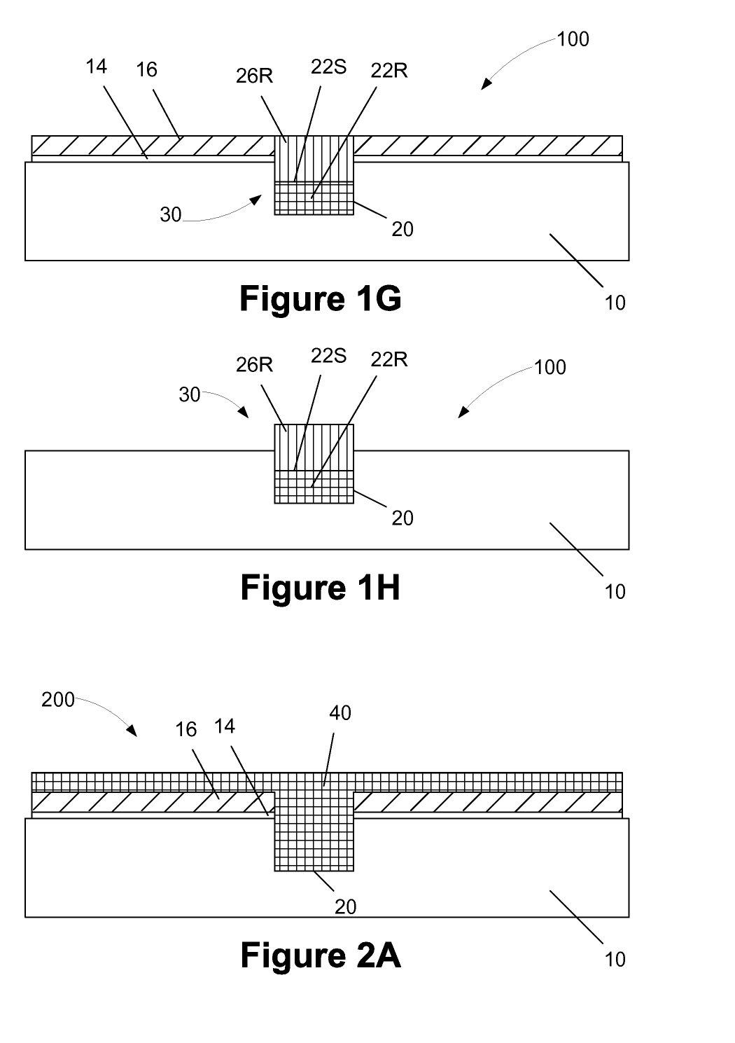

FIG. 1A is a simplified view of an illustrative semiconductor device 100 at an early stage of manufacturing. The semiconductor device 100 is formed above an illustrative bulk semiconducting substrate 10 having an upper surface 10S. The substrate 10 may have a variety of configurations, such as the depicted bulk silicon configuration. The substrate 10 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all forms of semiconductor structures. The substrate 10 may also be made of materials other than silicon.

In FIG. 1A, the device 100 is depicted at the point of fabrication where an illustrative protection layer 14, e.g., a screen or pad oxide layer, and a polish stop layer 16, e.g., a pad nitride layer, have been formed above the substrate 10. Also depicted in FIG. 1A is a patterned mask layer 18, e.g., a patterned photoresist mask that may be formed using traditional photolithography tools and techniques. In one illustrative example, the protection layer 14 may be a pad oxide layer having a thickness on the order of about 10 nm, and it may be formed by performing a thermal growth process. In one illustrative example, the polish stop layer 16 may be a pad nitride layer having a thickness on the order of about 80 nm, and it may be formed by performing a chemical vapor deposition (CVD) process.

Thereafter, as shown in FIG. 1B, an etching process, such as a reactive ion etching process, is performed through the mask layer 18 to pattern the protection layer 14 and the polish stop layer 16. FIG. 1C depicts the device 100 after the masking layer 18 has been removed and an etching process, such as a reactive ion etching process, has been performed to form a trench 20 in the substrate 10 using the patterned protection layer 14 and polish stop layer 16 as an etch mask. For ease of illustration, the trench 20 is depicted as having a generally rectangular cross-section. In real-world devices, the sidewalls of the trench 20 will likely be somewhat inwardly tapered. The dimensions of the trench 20 may vary depending on the particular application. In current day devices, the trench 20 may have a depth of about 100-400 nm and a width of about 30-50 nm.

Next, as shown in FIG. 1D, in one illustrative embodiment, an insulating material 22 is formed so as to over-fill the trench 20. The insulating material 22 may be comprised of a variety of different insulating materials that may be formed using a variety of techniques. In one illustrative example, the insulating material 22 may be a spin-on glass material that is formed on the wafer using traditional spin-coating tools and techniques so as to overfill the trench 20. In other illustrative embodiments, the insulating material 22 may be a flowable oxide material that may be formed using common techniques employed to form such flowable oxide materials as generally described further below. In general, the spin-on glass material that may be employed in some embodiments disclosed herein is a solvent-based liquid that is applied to substrates using a spin-coat process that is typically used to form a thin, solid film exhibiting the properties of silicon dioxide after curing. The basic spincoating process involves depositing a small amount of the liquid on the substrate 10, rotating the substrate 10 at a high rate to evenly distribute the liquid across the substrate 10, allowing the liquid to form a solid film, performing a low temperature (e.g., <250° C.) heating process to partially cure the glass material, and then performing a second heating process at a higher temperature (about 400-1100° C.) to fully cure the spin-on glass material.

Then, as shown in FIG. 1E, in one illustrative example, using the techniques disclosed herein, an etching process, either dry or wet, is performed on the fully formed insulating material 22 to thereby define a lower isolation structure 22R. In one illustrative embodiment, the lower isolation structure 22R may have a thickness or depth 22T that may be about ½-⅔ of the overall depth 20D of the trench 20. In one example, the upper surface 22S may typically be about 10-100 nm below the upper surface 10S of the substrate 10. In one illustrative example, the insulating material 22 may be a flowable oxide material offered by AZ Electronics and Applied Materials.

Next, as shown in FIG. 1F, a deposition process is performed to form a layer of insulating material 26 on the device 100 on top of the lower isolation structure 22R and to over-fill the trench 20. The layer of insulating material 26 may be comprised of a variety of different materials, such as, for example, silicon dioxide, etc., and it may be made using a variety of different processes, e.g., chemical vapor deposition (CVD), atomic layer deposition (ALD), etc., or plasma-enhanced versions of those processes. In one illustrative embodiment, the layer of insulating material 26 may be a silicon dioxide material made using a well-known HDP (High Density Plasma) process. Silicon dioxide material made using an HDP process will be referred to as an “HDP silicon dioxide.”

Next, as shown in FIG. 1G, a CMP process is performed to remove the portions of the layer of insulating material 26 positioned above the surface of the polish stop layer 16. This results in the formation of the upper isolation structure 26R of the overall trench isolation structure 30 on top of the lower isolation structure 22R. Thereafter, an etching or deglazing process is performed to insure that the surface of the polish stop layer 16 is free of any remnants of the layer of insulating material 26. This deglaze process may reduce the thickness of the upper isolation structure 26R slightly, but such thickness reduction is not depicted in FIG. 1G. Then, as shown in FIG. 1H, one or more etching processes, wet or dry, are performed to remove the polish stop layer 16 and the protective layer 14.

In the illustrative example depicted herein, the novel STI structure 30 disclosed herein comprises the upper isolation structure 26R and the lower isolation structure 22R made of a spin-on glass material or a flowable oxide material. In one illustrative example, the upper isolation structure 26R has a higher etch resistance to an etchant, such as a dilute HF acid, than does the lower isolation structure 22R. In a more specific example, where the upper isolation structure 26R and the lower isolation structure 22R are comprised of the same material, e.g., silicon dioxide, the upper isolation structure 26R has a higher etch resistance to a dilute HF acid etchant than does the lower isolation structure 22R. Thus, the novel STI structure 30 disclosed herein is better able to resist degradation in subsequent processing operations that are performed on the device 100. That is, the integrity of the STI structure 30 disclosed herein is greater than the integrity of prior art STI structures.

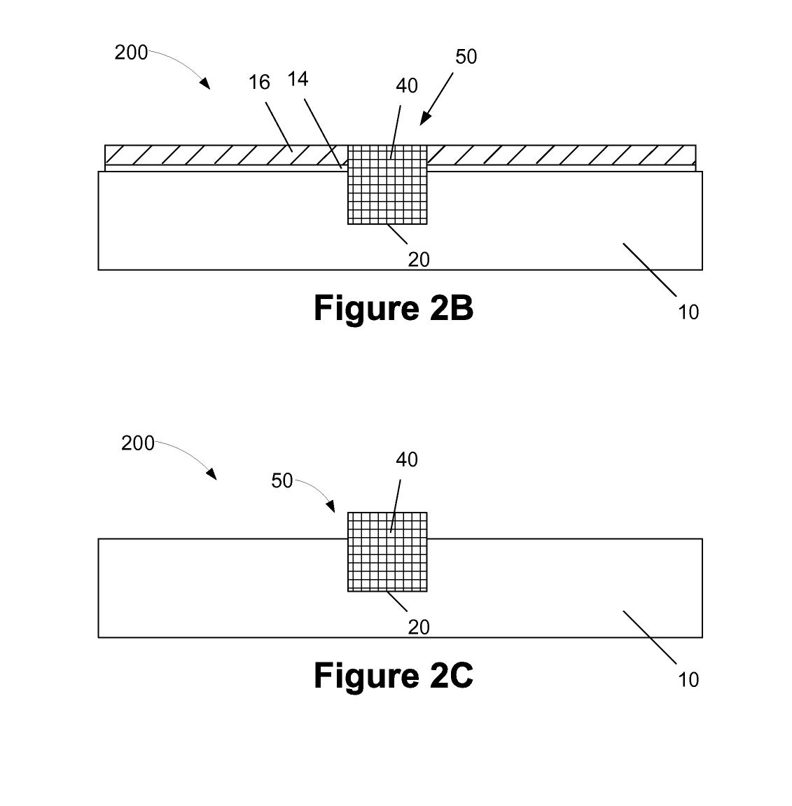

FIGS. 2A-2C depict an alternative method of forming STI structures for integrated circuit devices. In FIG. 2A, the device 200 is depicted at the point of fabrication where the protection layer 14, the polish stop layer 16 and the trench 20 have all been formed in the substrate as described previously. An insulating material 40 is then formed on the substrate 10 so as to overfill the trench 20. In one illustrative embodiment, the insulating material 40 may be a spin-on glass material (such as those described previously) or a flowable oxide material. A flowable oxide material may be applied using spin-coating techniques similar to those described above for the spin-on glass material, techniques that are well known to those skilled in the art. For example, the flowable oxide material may be initially applied by performing a spin-coating process at room temperature to spread the material across the substrate 10 and to fill the trench 20. The flowable oxide material may then be baked for a relatively short duration (about 1 minute) at a temperature of about 150° C. to initially drive off volatile components. Thereafter, the flowable oxide material may be heated to a temperature of about 200° C. to provide additional curing and it may then be heated at about 350° C. to reflow the material. Due to the number of heating processes employed in using the flowable oxide material, the temperatures and/or durations of one or more of these heating steps may be adjusted so as to modify the hardness characteristics of the resulting oxide material. By increasing the temperature and/or duration of one or more of these heating steps, the density of the flowable oxide material increases, which increases its hardness. Performing steam-based anneal processes can also increase the hardness of the flowable oxide material.

Next, as shown in FIG. 2B, a CMP process is performed to remove the portions of the layer of insulating material 40 positioned above the surface of the polish stop layer 16. This results in the formation of trench isolation structure 50 in the trench 20. Thereafter, an etching or deglazing process is performed to insure that the surface of the polish stop layer 16 is free of any remnants of the layer of insulating material 40. This deglaze process may reduce the thickness of the isolation structure 50 slightly, but such thickness reduction is not depicted in FIG. 2B. Then, as shown in FIG. 2C, one or more etching processes, wet or dry, are performed to remove the polish stop layer 16 and the protective layer 14.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a trench in a semiconducting substrate;
forming a lower isolation structure comprised of an insulating material in said trench, said lower isolation structure having an upper surface that is below an upper surface of said substrate; and
forming an upper isolation structure above said lower isolation structure, wherein a portion of said upper isolation structure is positioned within said trench.

2. The method of claim 1, wherein said upper isolation structure contacts said upper surface of said lower isolation structure.

3. The method of claim 1, wherein said insulating material is a spin-on glass material.

4. The method of claim 1, wherein said insulating material is a flowable oxide material.

5. The method of claim 3, wherein said lower isolation structure is formed by:
performing a spin-coating process to position said spin-on glass material at least in said trench;
after performing said spin-coating process, performing a heating process to at least partially cure said spin-on glass material; and
after performing said heating process, performing an etching process on said spin-on glass material to remove a portion of said spin-on glass material and thereby define said lower isolation structure.

6. The method of claim 1, wherein said upper isolation structure has a higher etch resistance to a dilute HF acid etchant than does said insulating material.

7. The method of claim 1, wherein said upper isolation structure is an HDP silicon dioxide material.

8. A method, comprising:
forming a trench in a semiconducting substrate;
performing a spin-coating process to position a spin-on glass material at least in said trench;
after performing said spin-coating process, performing a heating process to at least partially cure said spin-on glass material;
after performing said heating process, performing an etching process on said spin-on glass material to remove a portion of said spin-on glass material and thereby define said lower isolation structure; and
forming an upper isolation structure above said lower isolation structure, wherein a portion of said upper isolation structure is positioned within said trench.

9. The method of claim 8, wherein said upper isolation structure contacts said upper surface of said lower isolation structure.

10. The method of claim 8, wherein said upper isolation structure has a higher etch resistance to a dilute HF acid etchant than does said spin-on glass material.

11. The method of claim 8, wherein forming said upper isolation structure comprises:
performing a deposition process to deposit a layer of insulating material above said substrate, said lower isolation structure and in said trench; and
performing a chemical mechanical polishing process to remove at least portions of said layer of insulating material positioned outside of said trench to thereby define said upper isolation structure.

12. The method of claim 8, wherein forming said upper isolation structure comprises:
performing a high density plasma (HDP) deposition process to deposit a layer of HDP silicon dioxide above said substrate, said lower isolation structure and in said trench; and
removing portions of said layer of HDP silicon dioxide to thereby define an upper isolation structure above said lower isolation structure, wherein a portion of said upper isolation structure is positioned within said trench.

13. A method, comprising:
forming a trench in a semiconducting substrate;
performing a spin-coating process to position a flowable oxide material at least in said trench;
after performing said spin-coating process, performing a heating process to at least partially cure said flowable oxide material;
after performing said heating process, performing an etching process on said flowable oxide material to remove a portion of said flowable oxide material and thereby define said lower isolation structure; and
forming an upper isolation structure above said lower isolation structure, wherein a portion of said upper isolation structure is positioned within said trench.

14. The method of claim 13, wherein said upper isolation structure contacts said upper surface of said lower isolation structure.

15. The method of claim 13, wherein said upper isolation structure has a higher etch resistance to a dilute HF acid etchant than does said flowable oxide material.

16. The method of claim 13, wherein forming said upper isolation structure comprises:
performing a deposition process to deposit a layer of insulating material above said substrate, said lower isolation structure and in said trench; and
performing a chemical mechanical polishing process to remove at least portions of said layer of insulating material positioned outside of said trench to thereby define said upper isolation structure.

17. The method of claim 13, wherein forming said upper isolation structure comprises:
performing a high density plasma (HDP) deposition process to deposit a layer of HDP silicon dioxide above said substrate, said lower isolation structure and in said trench; and
removing portions of said layer of HDP silicon dioxide to thereby define an upper isolation structure above said lower isolation structure, wherein a portion of said upper isolation structure is positioned within said trench.

18. A device, comprising:
a semiconducting substrate;
a trench formed in said substrate;
a lower isolation structure comprised of a spin-on glass material or a flowable oxide material positioned in said trench, said lower isolation structure having an upper surface that is below an upper surface of said substrate; and
an upper isolation structure positioned above said lower isolation structure, wherein a portion of said upper isolation structure is positioned within said trench.

19. The device of claim 18, wherein said upper isolation structure contacts said upper surface of said lower isolation structure.

20. The device of claim 18, wherein said upper isolation structure is comprised of an HDP silicon dioxide material.

21. The device of claim 18, wherein said upper isolation structure has a higher etch resistance to a dilute HF acid etchant than does said spin-on glass material.

22. The device of claim 18, wherein said upper surface of said lower isolation structure is at least 10-100 nm below said upper surface of said substrate.

23. A method, comprising:
forming a trench in a semiconducting substrate; and
forming an isolation structure comprised of a spin-on glass material or a flowable oxide material in said trench.

24. The method of claim 23, wherein forming said isolation structure comprises:
performing a spin-coating process to spread said spin-on glass material or said flowable oxide material across said substrate so as to overfill said trench;
performing at least one heating process on said spin-on glass material or said flowable oxide material; and
after performing said at least one heating process, performing a chemical mechanical polishing process on said spin-on glass material or said flowable oxide material to thereby define said isolation structure.

25. The method of claim 23, wherein forming said isolation structure comprises:
performing a spin-coating process to spread said spin-on glass material or said flowable oxide material across said substrate so as to overfill said trench;
performing at least one heating process on said spin-on glass material or said flowable oxide material;
after performing said at least one heating process, performing an etching process on said spin-on glass material or said flowable oxide material to thereby define said isolation structure.
